(19) United States
(12) Patent Application Publication
(10) Pub. No.: US 2024/0224509 A1
(43) Pub. Date: Jul. 4, 2024

(54) DYNAMIC RANDOM ACCESS MEMORY DEVICE AND METHOD FOR FORMING THE SAME

(71) Applicant: Powerchip Semiconductor Manufacturing Corporation, Hsinchu (TW)

(72) Inventor: Wen-Yueh Chang, Hsinchu City (TW)

(73) Assignee: Powerchip Semiconductor Manufacturing Corporation, Hsinchu (TW)

(21) Appl. No.: 18/177,766

(22) Filed: Mar. 3, 2023

(30) Foreign Application Priority Data
Jan. 4, 2023 (TW) 112100177

(51) Int. Cl. H10B 12/00; H01L 25/16; H01L 29/786; H10B 80/00

(52) U.S. Cl. CPC H10B 12/395; H01L 25/16; H01L 29/7869; H01L 29/78696; H10B 12/0383; H10B 12/053; H10B 12/312; H10B 12/482; H10B 12/488; H10B 80/00

(57) ABSTRACT

A dynamic random access memory device and a method for forming the same are provided. The dynamic random access memory device includes a substrate, multiple word lines, multiple bit lines, and multiple memory device layers. The word lines extend toward a first direction. The bit lines extend toward a second direction. The second direction is orthogonal to the first direction. The memory device layers are disposed on the substrate and stacked in a normal direction of the substrate. Each memory device layers includes multiple memory cells and a capacitor voltage transmission line. The memory cells include a thin film transistor and a capacitor. Each memory cells is electrically connected to a corresponding word line and a corresponding bit line. The capacitor voltage transmission line is electrically connected to the capacitor. The word lines or the bit lines extend in a same direction as the capacitor voltage transmission line.

### CROSS-REFERENCE TO RELATED APPLICATION

This application claims the priority benefit of Taiwan application serial no. 112100177, filed on Jan. 4, 2023. The entirety of the above-mentioned patent application is hereby incorporated by reference herein and made a part of this specification.

### BACKGROUND

### Technical Field

The disclosure relates to a dynamic random access memory device and a method for forming the same, and more particularly, to a dynamic random access memory device with 1T1C structure and a method for forming the same.

### Description of Related Art

With the progress of semiconductor technology, the size of a dynamic random access memory device is shrinking, so that the area occupied by the dynamic random access memory device is reduced and its device density is increased. Thus, it is one of the current development goals to seek ways to further reduce the occupied area of the dynamic random access memory device so as to increase its density.

### SUMMARY

The disclosure provides a dynamic random access memory device and a method for forming the same. An integration of this memory device may be further improved.

The dynamic random access memory device of an embodiment of disclosure includes a substrate, multiple word lines, multiple bit lines, and multiple memory device layers. The word lines extend toward a first direction. The bit lines extend toward a second direction. The second direction is orthogonal to the first direction. The memory device layers are disposed on the substrate and stacked in a normal direction of the substrate. Each of the memory device layers includes multiple memory cells and a capacitor voltage transmission line. The memory cells include a thin film transistor and a capacitor. Each of the memory cells is electrically connected to a corresponding word line and a corresponding bit line. The capacitor voltage transmission line is electrically connected to the capacitor. The word lines or the bit lines extend in a same direction as the capacitor voltage transmission line.

The method for forming the dynamic random access memory device of an embodiment of disclosure is described below. A substrate having a trench is provided. A source of a thin film transistor and a first electrode of a capacitor are disposed in the trench. A first dielectric material layer is formed on the substrate. A word line, a gate of the thin film transistor, a second electrode of the capacitor, and a capacitor voltage transmission line are formed on the first dielectric material layer. The word line and the capacitor voltage transmission line extend toward a first direction. A portion of the source is exposed by removing a portion of the first dielectric material layer. An active layer is formed on the substrate. The active layer is electrically connected to the source. A memory device layer is formed by forming a bit line and a drain of the thin film transistor on the substrate. The bit line extends toward a second direction and connects to the drain, and the drain is electrically connected to the active layer. The memory device layers are stacked in a normal direction of the substrate. A channel layer in the active layer and the gate are disposed correspondingly in the second direction.

The method for forming the dynamic random access memory device of another embodiment of disclosure is described below. A substrate having a trench is provided. A first conductor layer is disposed in the trench, and the first conductor layer includes a gate of a thin film transistor and a capacitor voltage transmission line. A dielectric layer covering the first conductor layer is formed on the substrate. An active layer is formed on the substrate. The active layer is disposed correspondingly to the gate. A memory device layer is formed by forming a second conductor layer on the substrate. The second conductor layer includes a source and a drain of the thin film transistor. The source and the drain are electrically connected to the active layer. The memory device layers are stacked in a normal direction of the substrate. Multiple openings are formed in the memory device layers. The openings extend in the normal direction of the substrate. A third conductor layer is formed in the openings. The first conductor layer further includes multiple word lines and the third conductor layer includes multiple bit lines; or the third conductor layer includes the word lines and the second conductor layer further includes the bit lines. The word lines are orthogonal to the bit lines, and the word lines or the bit lines extend in a same direction as the capacitor voltage transmission line.

Based on the above, some embodiments of the disclosure provide a dynamic random access memory device with a three-dimensional structure and a method for forming the same. Based on this, the disclosure may further reduce the occupied area of the dynamic random access memory device and increase the density of the dynamic random access memory device.

### BRIEF DESCRIPTION OF THE DRAWINGS

FIG. 1A is a top schematic view of a dynamic random access memory device according to the first embodiment of the disclosure.

FIG. 1B is a cross-sectional schematic view cut according to the profile line A-A′ of FIG. 1A.

FIG. 2A to FIG. 2C are top schematic views of a method for forming a dynamic random access memory device according to the first embodiment of the disclosure.

FIG. 3A to FIG. 3C are cross-sectional schematic views of a method for forming a dynamic random access memory device according to the first embodiment of the disclosure.

FIG. 4A is a top schematic view of a dynamic random access memory device according to the second embodiment of the disclosure.

FIG. 4B is a cross-sectional schematic view cut according to the profile line B-B′ of FIG. 4A.

FIG. 5A to FIG. 5C are top schematic views of a method for forming a dynamic random access memory device according to the second embodiment of the disclosure.

FIG. 6A to FIG. 6C are cross-sectional schematic views of a method for forming a dynamic random ass memory device according to the second embodiment of the disclosure.

FIG. 7A is a top schematic view of a dynamic random access memory device according to the third embodiment of the disclosure.

FIG. 7B is a cross-sectional schematic view cut according to the profile line C1-C1′ of FIG. 7A.

FIG. 7C is a cross-sectional schematic view cut according to the profile line C2-C2′ of FIG. 7A.

FIG. 8A to FIG. 8C are top schematic views of a method for forming a dynamic random access memory device according to the third embodiment of the disclosure.

FIG. 9A to FIG. 9C are cross-sectional schematic views of a method for forming a dynamic random access memory device according to the third embodiment of the disclosure.

### DESCRIPTION OF THE EMBODIMENTS

Unless otherwise defined, all terms (including technical and scientific terms) used herein have the same meaning as that commonly understood by one of ordinary skill in the art to which this disclosure belongs. It should be further understood that terms such as those defined in commonly used dictionaries should be construed as having meanings consistent with their meanings in the context of the related art and the disclosure, and are not to be construed as idealized or excessive formal meaning, unless expressly defined as such herein.

The schematic views in this article are only used to illustrate the embodiments of the disclosure. Thus, the shape, amount, and scale of each of the devices shown in the schematic views should not be used to limit the disclosure.

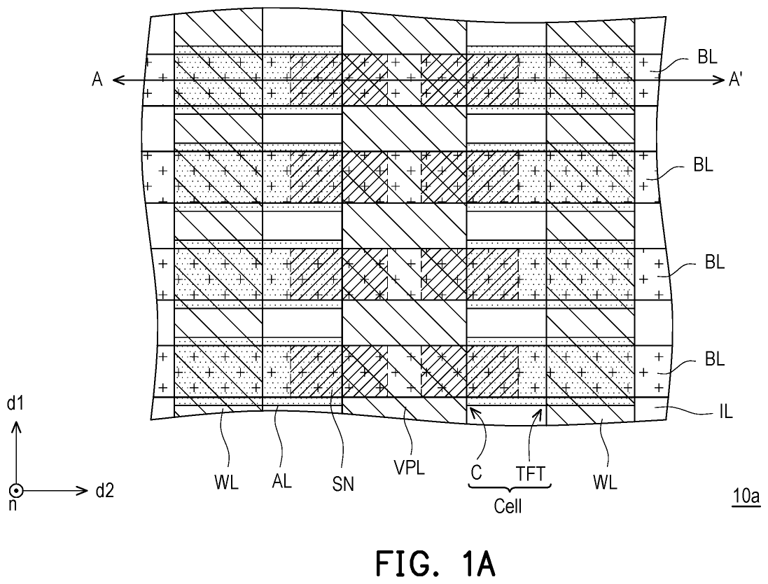

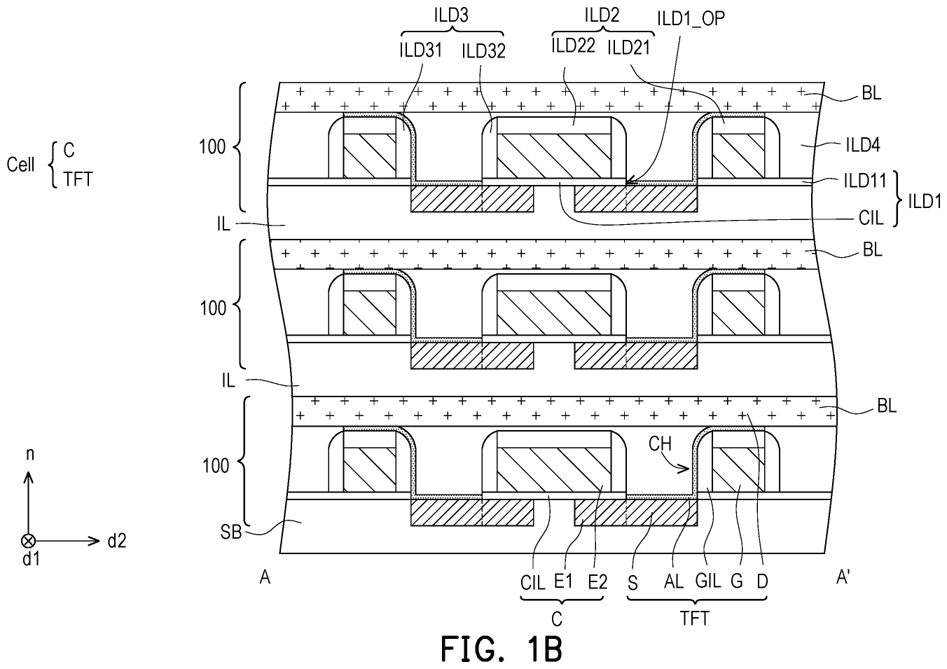

FIG. 1A is a top schematic view of a dynamic random access memory device according to the first embodiment of the disclosure, and FIG. 1B is a cross-sectional schematic view cut according to the profile line A-A′ of FIG. 1A.

Referring to FIG. 1A and FIG. 1B at the same time, a dynamic random access memory device 10a of this embodiment includes a substrate SB, multiple memory device layers 100, multiple word lines WL, and multiple bit lines BL.

The substrate SB is, for example, an inter layer dielectric (ILD) layer or an inter metal dielectric (IMD) layer on a semiconductor substrate or a semiconductor on insulator (SOI) substrate. The semiconductor material in the semiconductor substrate and the semiconductor on insulator substrate may include, for example, an elemental semiconductor, an alloy semiconductor, or a compound semiconductor. For example, the elemental semiconductor may include Si or Ge, the alloy semiconductor may include SiGe, SiC, SiGeC, etc., and compound semiconductor may include III-V group semiconductor material or II-VI group semiconductor material.

The word lines WL are, for example, disposed on the substrate SB and extend toward a first direction d1. The material of the word line WL may include, for example, metal, metal compound (such as metal nitride), alloy, semiconductor material or a combination thereof, and the disclosure is not limited thereto.

The bit lines BL are, for example, disposed on the substrate SB and extend toward a second direction d2. The second direction d2 is, for example, orthogonal to the first direction d1. The material of the bit line BL may include, for example, metal, metal compound (such as metal nitride), alloy, semiconductor material or a combination thereof, and the disclosure is not limited thereto.

The memory device layers 100 are, for example, disposed on the substrate SB and stacked in a normal direction n of the substrate SB. The normal direction n of the substrate SB is, for example, orthogonal to the first direction d1 and the second direction d2. For example, FIG. 1B shows that three memory cell layers are sequentially stacked in the normal direction n of the substrate SB. An isolation layer IL is disposed between adjacent memory cell layers 100. The material of the isolation layer IL may include, for example, silicon oxide, silicon nitride, silicon oxynitride or a combination thereof, and the disclosure is not limited thereto. It is worth noting that although FIG. 1B only shows three memory cell layers 100, the disclosure does not limit the amount of memory cell layers 100 included in the dynamic random access memory device 10a.

In this embodiment, each of the memory device layers 100 includes multiple memory cells and a capacitor voltage transmission line VPL. Each of the memory cells includes, for example, a thin film transistor TFT and a capacitor C. The connection between the thin film transistor TFT and the capacitor C may form a storage node SN, as shown in FIG. 1A. In this embodiment, the memory cell is a structure of 1T1C (a thin film transistor and a capacitor), but the disclosure is not limited thereto. In some embodiments, each of the memory cells is electrically connected to a corresponding word line WL and a corresponding bit line BL for performing writing and/or reading operations by applying a voltage to the word line WL and/or bit line BL.

The thin film transistor TFT includes, for example, a gate G, a gate dielectric layer GIL, a source S, a drain D, and an active layer AL. In some embodiments, the thin film transistor TFT is turned on for writing and/or reading operations.

The gate G is, for example, disposed on the substrate SB. In this embodiment, the gate G and the word line WL belong to the same layer. From another perspective, the gate G is directly connected to the word line WL.

The gate dielectric layer GIL is, for example, disposed on a sidewall of the gate G. For example, the gate dielectric layer GIL is disposed on the sidewall of the gate G in the second direction d2, but the disclosure is not limited thereto. The material of the gate dielectric layer GIL may include, for example, silicon oxide, silicon nitride, silicon oxynitride or a combination thereof, and the disclosure is not limited thereto.

The active layer AL is, for example, disposed on the gate dielectric layer GIL and is, for example, disposed corresponding to the gate G. The part of the active layer AL overlapping with the gate G in the second direction d2 is, for example, a channel layer CH. From another perspective, the gate dielectric layer GIL is, for example, disposed between the gate G and the channel layer CH of the active layer AL. In this embodiment, the material of active layer AL includes oxide semiconductor. For example, the material of the active layer AL may include indium gallium zinc oxide (IGZO), but the disclosure is not limited thereto. Since the band gap of oxide semiconductor is larger than that of silicon, in response to the material of the active layer AL including oxide semiconductor, the thin film transistor TFT may have a lower leakage electric current in the off state, which reduces the speed of charge loss in the capacitor C. Thus, the time for the dynamic random access memory device 10a of this embodiment to save the data is increased.

The source S and the drain D are, for example, separated from each other, and are electrically connected to the active layer AL respectively. In this embodiment, the source S is disposed in a trench T of the substrate SB, and the drain D is disposed on the gate G and belongs to the same layer as the bit line BL. From another perspective, the drain D is directly connected to the bit line BL.

Since the channel layer CH of the thin film transistor TFT extends along the normal direction n of the substrate SB and is disposed between the source S and the drain D in the normal direction n of the substrate SB. Thus, the thin film transistor TFT of this embodiment is a vertical transistor, but the disclosure is not limited thereto.

Based on this, by providing the thin film transistor TFT with a vertical transistor design, the drain D of the thin film transistor TFT may be in the same layer as the bit line BL, so that the bit line BL is directly connected to the drain D of the thin film transistor TFT. In this way, the integration of the dynamic random access memory device 10a is improved.

The capacitor C includes, for example, an electrode E1, a capacitor dielectric layer CIL, and an electrode E2, and is electrically connected to the thin film transistor TFT. In some embodiments, the capacitor C is used to store charge, and whether there is charge in capacitor C is represented by digits “1” and “0”, respectively.

The electrode E1 is, for example, disposed in the trench T of the substrate SB and belongs to the same layer as the source S. In this embodiment, the electrode E1 is connected to the source S as a storage node SN, so that the capacitor C is electrically connected to thin film transistor TFT. In addition, similarly, by providing the thin film transistor TFT with a vertical transistor design, the source S of the thin film transistor TFT may be in the same layer as the electrode E1 of the capacitor C, so that the electrode E1 of the capacitor C is directly connected to the source S of the thin film transistor TFT. In this way, the integration of the dynamic random access memory device 10a is improved.

The capacitor dielectric layer CIL is, for example, disposed on the substrate SB, and at least partially overlaps with the electrode E1 in the normal direction n of the substrate SB. The material of the capacitor dielectric layer CIL may include, for example, silicon oxide, silicon nitride, silicon oxynitride or a combination thereof, but the disclosure is not limited thereto. In other embodiments, the material of the capacitor dielectric layer CIL may include a dielectric material with a relatively high dielectric constant, which may be oxides of the following elements or combinations thereof, such as: hafnium, zirconium, aluminum, titanium, lanthanum, yttrium, gadolinium, or tantalum.

For example, the electrode E2 is disposed on the substrate SB and belongs to the same layer as the gate G, and at least partially overlaps with the electrode E1 in the normal direction n of the substrate SB. From another perspective, the capacitor dielectric layer CIL is, for example, disposed between the electrode E1 and the electrode E2.

The capacitor voltage transmission line VPL is, for example, disposed on the substrate SB and electrically connected to the capacitor C. In this embodiment, the capacitor voltage transmission line VPL and the electrode E2 of the capacitor C belong to the same layer, and is connected to the electrode E2 of the capacitor C. The capacitor voltage transmission line VPL is, for example, used to provide a capacitor voltage to the capacitor C. In this embodiment, the capacitor voltage transmission line VPL and the word line WL extend toward the same direction. That is, the capacitor voltage transmission line VPL extends toward the first direction d1. In this embodiment, the capacitor voltage transmission line VPL is disposed between adjacent word lines WL in the second direction d2, so that the capacitor voltage transmission line VPL is shared by two adjacent memory cells Cell in the second direction d2. In this way, the integration of the dynamic random access memory device 10a is improved.

In this embodiment, the dynamic random access memory device 10a further includes a dielectric layer ILD11, a dielectric layer ILD2, a dielectric layer ILD3, and a dielectric layer ILD4.

The dielectric layer ILD11 is, for example, disposed on the substrate SB, and is, for example, disposed between the substrate SB and the gate G of the thin film transistor TFT. In this embodiment, the dielectric layer ILD11 at least partially overlaps with the gate G in the normal direction n of the substrate SB. In addition, the dielectric layer ILD11 belongs to, for example, the same layer as the capacitor dielectric layer CIL. From another perspective, the dielectric layer ILD11 and the capacitor dielectric layer CIL are, for example, parts of the dielectric layer ILD1. The dielectric layer ILD1 has an opening ILD1_OP that exposes the source S of the thin film transistor TFT, so that the active layer AL is electrically connected to the source S, as shown in FIG. 1B.

The dielectric layer ILD2 is, for example, disposed on the dielectric layer ILD1. In this embodiment, the dielectric layer ILD2 includes a dielectric layer ILD21 and a dielectric layer ILD22. The dielectric layer ILD21 is disposed on the gate G, and the dielectric layer ILD22 is disposed on the electrode E2. From another perspective, the gate G is disposed between the dielectric layer ILD21 and the dielectric layer ILD11 in the normal direction n of the substrate SB, and the electrode E2 is disposed between the dielectric layer ILD22 and the capacitor dielectric layer CIL in the normal direction n of the substrate SB. The material of the dielectric layer ILD2 may include, for example, silicon oxide, silicon nitride, silicon oxynitride or a combination thereof, but the disclosure is not limited thereto.

The dielectric layer ILD3 is, for example, disposed on the dielectric layer ILD1. In this embodiment, the dielectric layer ILD3 includes a dielectric layer ILD31 and a dielectric layer ILD32. The dielectric layer ILD31 is disposed on the sidewall of the gate G, and the dielectric layer ILD32 is disposed on a sidewall of the electrode E2. From another perspective, the dielectric layer ILD31 is disposed on the sidewall of the gate G in the second direction d2, and the dielectric layer ILD32 is disposed on the sidewall of the electrode E2 in the second direction d2. In some embodiments, the dielectric layer ILD31 may extend toward the first direction d1 together with the word line WL, and the dielectric layer ILD32 may extend toward the first direction d1 together with the capacitor voltage transmission line VPL, but the disclosure is not limited thereto. In this embodiment, the dielectric layer ILD31 includes a gate dielectric layer GIL disposed between the active layer AL and the gate G, and detailed descriptions are omitted hereinafter. The material of the dielectric layer ILD3 may include, for example, silicon oxide, silicon nitride, silicon oxynitride or a combination thereof, but the disclosure is not limited thereto.

The dielectric layer ILD4 is, for example, disposed on the dielectric layer ILD1 and, for example, disposed between adjacent word lines WL and the capacitor voltage transmission line VPL. In some embodiments, the dielectric layer ILD4 may cover the dielectric layer ILD22 and the dielectric layer ILD32. In this embodiment, the dielectric layer ILD4 exposes at least part of the active layer AL, so that the active layer AL is electrically connected to the drain D. The material of the dielectric layer ILD4 may include, for example, silicon oxide, silicon nitride, silicon oxynitride or a combination thereof, but the disclosure is not limited thereto.

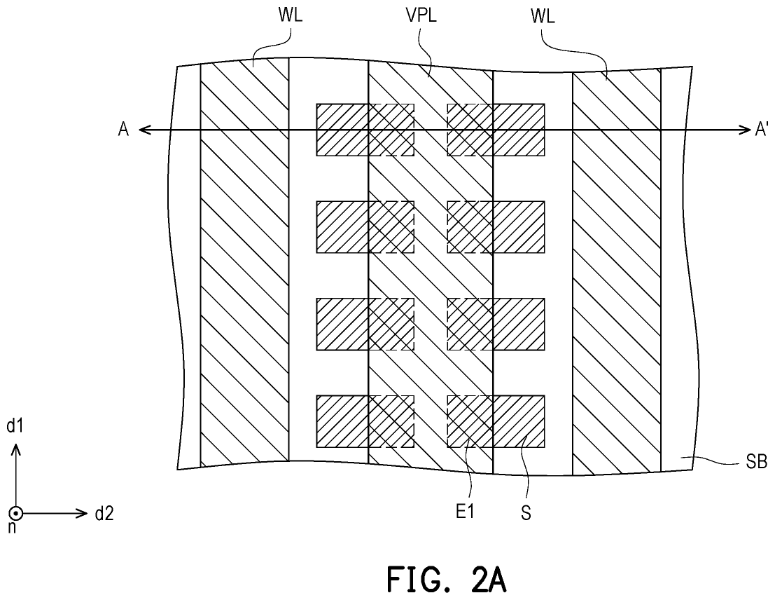

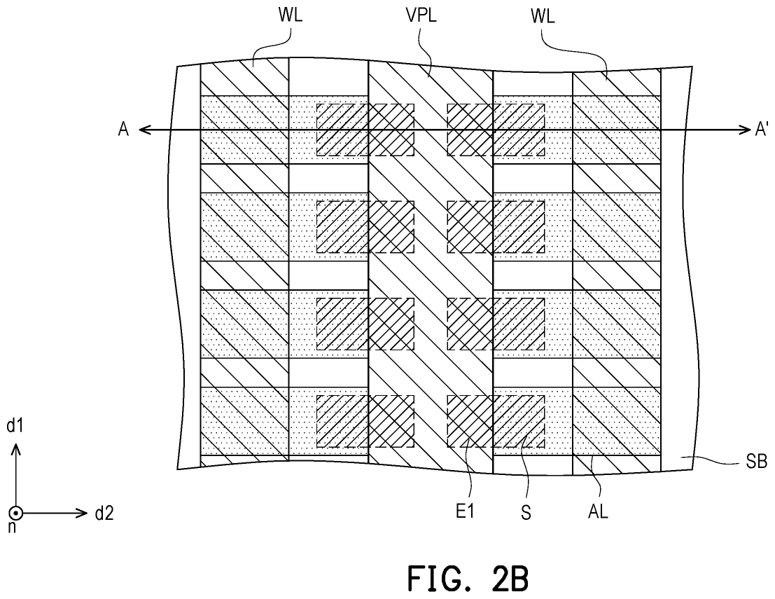

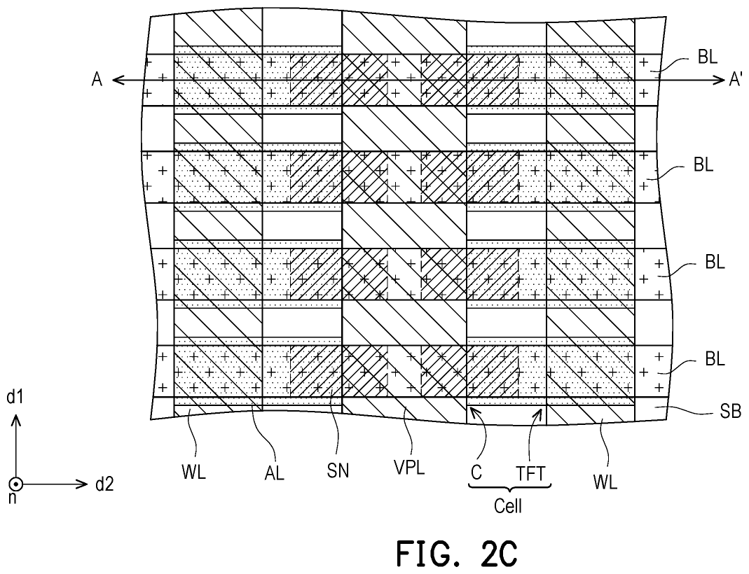

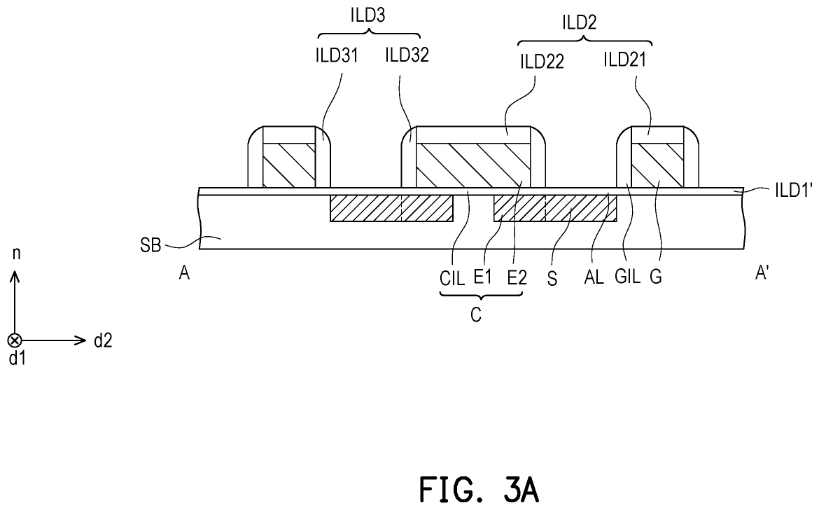

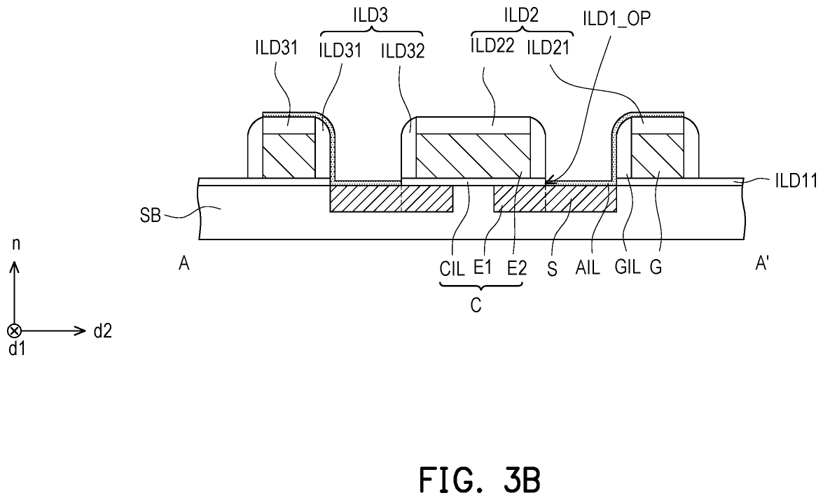

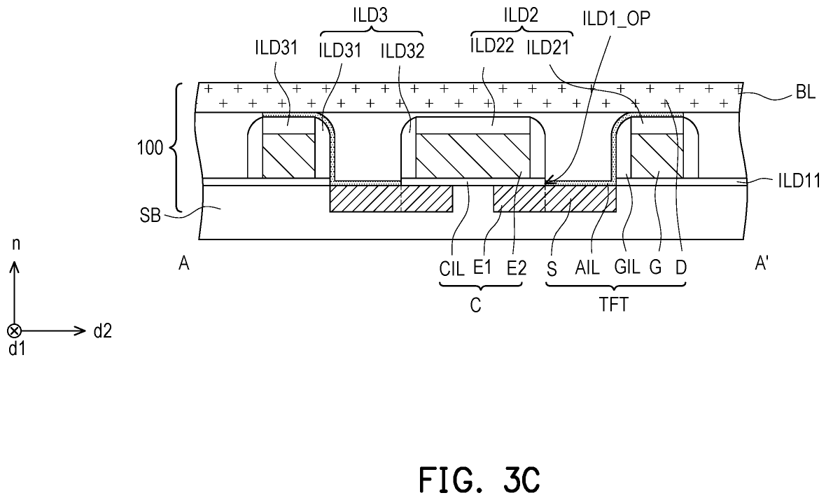

FIG. 2A to FIG. 2C are top schematic views of a method for forming a dynamic random access memory device according to the first embodiment of the disclosure, and FIG. 3A to FIG. 3C are cross-sectional schematic views of a method for forming a dynamic random access memory device according to the first embodiment of the disclosure. It is noted that the embodiments of FIG. 2A to FIG. 2C and FIG. 3A to FIG. 3C may use the reference numerals and a part of the contents of the embodiment of FIG. 1A and FIG. 1B, and the same or similar reference numerals are used to denote the same or similar elements, and the description of the same technical content is omitted.

Referring to FIG. 2A and FIG. 3A at the same time, the word line WL, the capacitor voltage transmission line VPL, and the dielectric layer ILD2 are formed on the substrate SB. The word line WL and the capacitor voltage transmission line VPL belong to the same layer (first conductor layer). The material of the substrate SB may refer to the aforementioned embodiment, and detailed descriptions are omitted hereinafter.

In this embodiment, the electrode E1 of the capacitor C and the source S of the thin film transistor TFT are formed in the substrate SB before forming the word line WL, the capacitor voltage transmission line VPL, and the dielectric layer ILD2 on the substrate SB. In some embodiments, the method for forming the electrode E1 of the capacitor C and the source S of the thin film transistor TFT in the substrate SB may include the following process, but the disclosure is not limited thereto. Firstly, a trench T is formed on the substrate SB. The trench T is formed, for example, by performing a patterning process to remove a part of the substrate SB. Next, a conductor material layer (not shown) filled in the trench T is formed on the substrate SB. Then, the conductor material layer outside the trench T is removed to form the electrode E1 of the capacitor C and the source S of the thin film transistor TFT.

In this embodiment, a dielectric material layer ILD1′ is also formed on the substrate SB before forming the word line WL, the capacitor voltage transmission line VPL, and the dielectric layer ILD2 on the substrate SB. The dielectric material layer ILD1′ covers the substrate SB and the electrode E1 and the source S disposed in the trench T.

In some embodiments, the method for forming word line WL, the capacitor voltage transmission line VPL, and the dielectric layer ILD2 on substrate SB may include the following process, but the disclosure is not limited thereto. Firstly, a conductor material layer (not shown) and a dielectric material layer (not shown) covering the substrate SB are sequentially formed on the substrate SB. Next, the dielectric layer ILD2 is formed by removing a part of the dielectric material layer by performing a patterning process. Then, an etching process is performed with the dielectric layer ILD2 as the mask to remove a part of the conductor material layer to form the word line WL and the capacitor voltage transmission line VPL, respectively. The word line WL and the capacitor voltage transmission line VPL, for example, extend along the first direction d1 and are separated from each other in the second direction d2. In addition, the word line WL and the capacitor voltage transmission line VPL are, for example, disposed on the dielectric material layer ILD1′ and the dielectric layer ILD2 is, for example, disposed on the word line WL and the capacitor voltage transmission line VPL. From another perspective, the word line WL and the capacitor voltage transmission line VPL are, for example, located between the dielectric material layer ILD1′ and the dielectric layer ILD2.

In this embodiment, a part of the word line WL is used as the gate G of the thin film transistor TFT, and a part of the capacitor voltage transmission line VPL is used as the electrode E2 of the capacitor C. That is, the gate G is directly connected to the word line WL, and the electrode E2 is directly connected to the capacitor voltage transmission line VPL, but the disclosure is not limited thereto. In addition, the dielectric layer ILD2 includes a dielectric layer ILD21 and a dielectric layer ILD22. The dielectric layer ILD21 is, for example, disposed on the gate G, and the dielectric layer ILD22 is, for example, disposed on the electrode E2.

In this embodiment, the dielectric layer ILD3 is further formed on the substrate SB. The dielectric layer ILD3 is disposed on the dielectric material layer ILD1′ and is located on a sidewall of the word line WL and a sidewall of the capacitor voltage transmission line VPL. In this embodiment, the dielectric layer ILD3 may extend toward the first direction d1 together with the word line WL and the capacitor voltage transmission line VPL, but the disclosure is not limited thereto. In addition, the dielectric layer ILD3 includes, for example, a dielectric layer ILD31 and a dielectric layer ILD32. The dielectric layer ILD31 is, for example, located on the sidewall of the gate G, and the dielectric layer ILD32 is, for example, located on the sidewall of the electrode E2.

Referring to FIG. 2B and FIG. 3B at the same time, the active layer AL is formed on the substrate SB. The active layer AL covers a part of the dielectric layer ILD21 and the part of the dielectric layer ILD31 (gate dielectric layer GIL) near the electrode E2. In some embodiments, the active layer AL may at least cover the dielectric layer ILD31 farther from the electrode E2, but the disclosure is not limited thereto.

In this embodiment, removing a part of the dielectric material layer ILD1′ to form a dielectric layer ILD1 with the opening ILD1_OP is also included before forming the active layer AL. The opening ILD1_OP of the dielectric layer ILD1 exposes at least a part of the source S. In some embodiments, the method for removing part of the dielectric material layer ILD1′ is, for example, by performing a patterning process. The aforementioned dielectric layer ILD3 is used as a mask in the patterning process, but the disclosure is not limited thereto. Based on this, the active layer AL is filled in the opening ILD1_OP of the dielectric layer ILD1 to be electrically connected to the source S. In addition, the dielectric layer ILD1 includes, for example, the dielectric layer ILD11 and the capacitor dielectric layer CIL. The dielectric layer ILD11, for example, at least partially overlaps with the gate G in the normal direction n of the substrate SB and the capacitor dielectric layer CIL, for example, at least partially overlaps with the electrode E2 in the normal direction n of the substrate SB.

Referring to FIG. 2C and FIG. 3C at the same time, the dielectric layer ILD4 and the bit line BL are formed on the substrate SB. The dielectric layer ILD4 is disposed on the dielectric layer ILD1, and the bit line BL is disposed on the dielectric layer ILD4. From another perspective, the dielectric layer ILD4 is located between the bit line BL and the dielectric layer ILD1. In some embodiments, the method for forming the dielectric layer ILD4 and the bit line BL on the substrate SB may include the following process, but the disclosure is not limited thereto. Firstly, a dielectric material layer (not shown) covering the active layer AL, the dielectric layer ILD2, and the dielectric layer ILD3 is formed on the substrate SB. Next, the dielectric layer ILD4 is formed removing a part of the dielectric material layer by performing a planarization process (e.g., including a grinding process, an etching process or a combination thereof). The dielectric layer ILD4 at least exposes a part of the active layer AL. Then, the bit line BL is formed on the dielectric layer ILD4. In this embodiment, the bit line BL extends toward the second direction d2, but the disclosure is not limited thereto. In addition, a part of the bit line BL is, for example, used as the drain D of the thin film transistor TFT. That is, the drain D is directly connected to the bit line BL, but the disclosure is not limited thereto. In addition, the drain D is electrically connected to the active layer AL exposed by the dielectric layer ILD4.

So far, the fabrication of the memory cell layer 100 is completed. However, the method for forming the memory cell layer 100 of the disclosure is not limited thereto.

Afterwards, referring to FIG. 1B, the memory cell layers 100 are stacked in the normal direction n of the substrate SB to form the dynamic random access memory device 10a with a three-dimensional structure. Thereby, while increasing the storage capacity of the dynamic random access memory device 10a, the occupied area of the dynamic random access memory device 10a is reduced, so as to facilitate the integration of the dynamic random access memory device 10a. In some embodiments, an isolation layer IL is provided between adjacent memory cell layers 100. The material of the isolation layer IL may refer to the aforementioned embodiment, and detailed descriptions are omitted hereinafter. It is worth noting that although FIG. 1B only shows three memory cell layers 100, the disclosure does not limit the amount of memory cell layers 100 included in the dynamic random access memory device 10a.

So far, the fabrication of the dynamic random access memory device 10a is completed. Although the method for forming the dynamic random access memory device 10a of this embodiment is described using the above method as an example, the method for forming the dynamic random access memory device of the disclosure is not limited thereto.

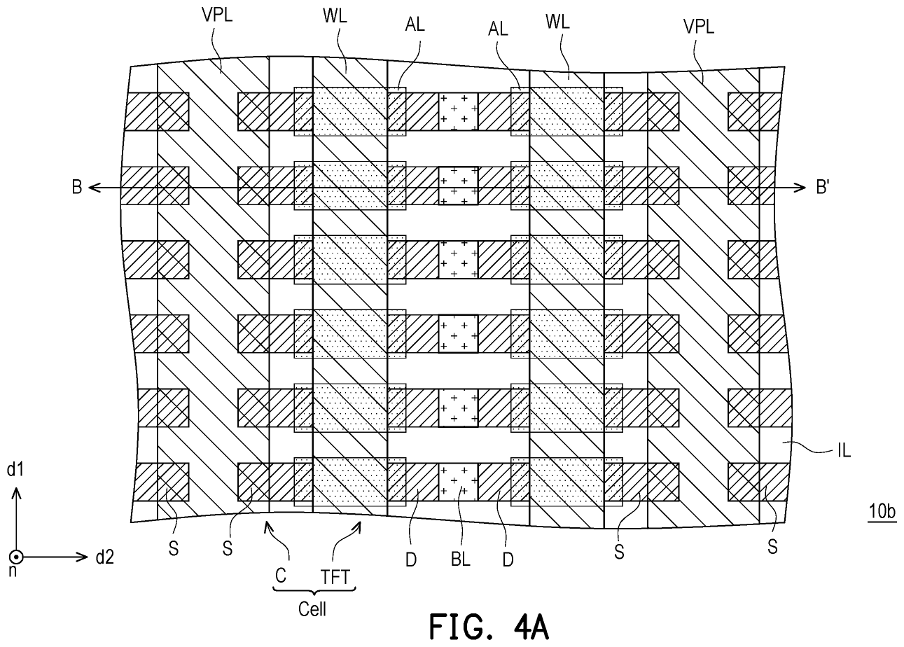

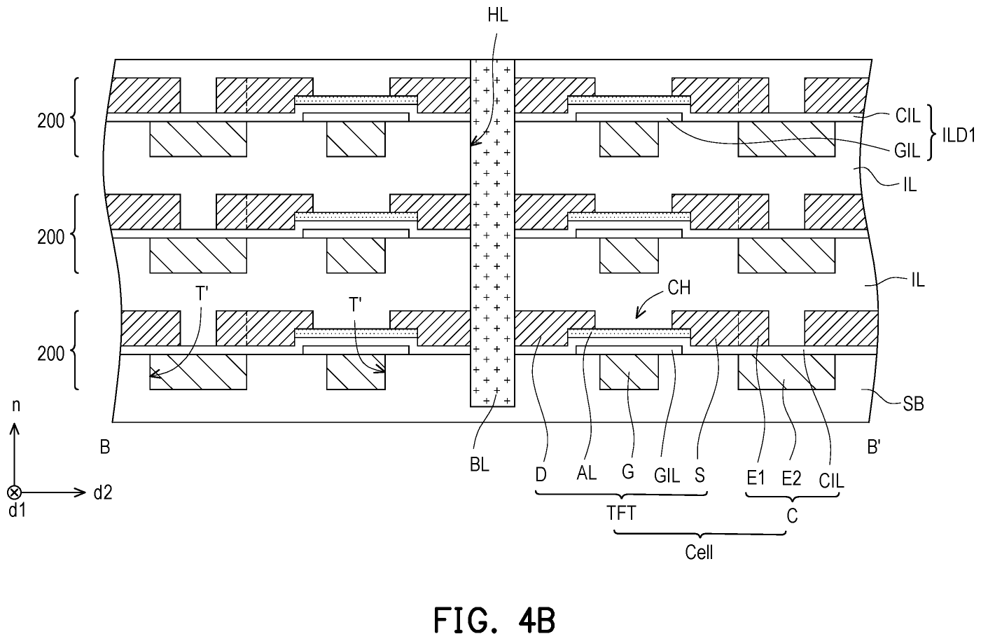

FIG. 4A is a top schematic view of a dynamic random access memory device according to the second embodiment of the disclosure, and FIG. 4B is a cross-sectional schematic view cut according to the profile line B-B′ of FIG. 4A.

Referring to FIG. 4A and FIG. 4B at the same time, the main difference between the dynamic random access memory device 10b of this embodiment and the dynamic random access memory device 10a is: (1) the word line WL and the capacitor voltage transmission line VPL are disposed in the trench T′ of the substrate SB middle; (2) the thin film transistor TFT in the memory cell layer 200 is a horizontal transistor; (3) the bit line BL extends toward the normal direction n of the substrate SB.

In the aforementioned (1), the word line WL and the capacitor voltage transmission line VPL are disposed in the trench T′ of the substrate SB. That is, the word line WL of this embodiment is an embedded word line, but the disclosure is not limited thereto. In addition, the gate G and the electrode E2 belonging to the same layer as the word line WL and the capacitor voltage transmission line VPL are also disposed in the trench T′ of the substrate SB.

In the aforementioned (2), the gate dielectric layer GIL is, for example, disposed on the substrate SB and covers the gate G. For example, the gate dielectric layer GIL is disposed on the gate G in the normal direction n of the substrate SB, but the disclosure is not limited thereto. The active layer AL is, for example, disposed on the gate dielectric layer GIL and is disposed corresponding to the gate G. The part of the active layer AL overlapping with the gate G is, for example, the channel layer CH. From another perspective, the gate dielectric layer GIL is, for example, disposed between the gate G and the channel layer CH of the active layer AL. For example, the source S and the drain D belong to the same layer, and partially cover the channel layer CH in the normal direction n of the substrate SB. In addition, the electrode E1 of the capacitor also belongs to the same layer as the drain D.

In this embodiment, the channel layer CH of the thin film transistor TFT extends along the second direction d2 and is disposed corresponding to the gate G in the normal direction n of the substrate SB. Thus, the thin film transistor TFT of this embodiment is a horizontal transistor, but the disclosure is not limited thereto.

In the aforementioned (3), the bit line BL extends toward the normal direction n of the substrate SB. In some embodiments, the bit line BL may penetrate multiple memory cell layers 200 in the normal direction n of the substrate SB. In this embodiment, the bit line BL is disposed between the drains D of adjacent thin film transistors TFT in the second direction d2, so that the bit line BL is shared by two adjacent memory cells in the second direction d2. In this way, the integration of the dynamic random access memory device 10b is improved.

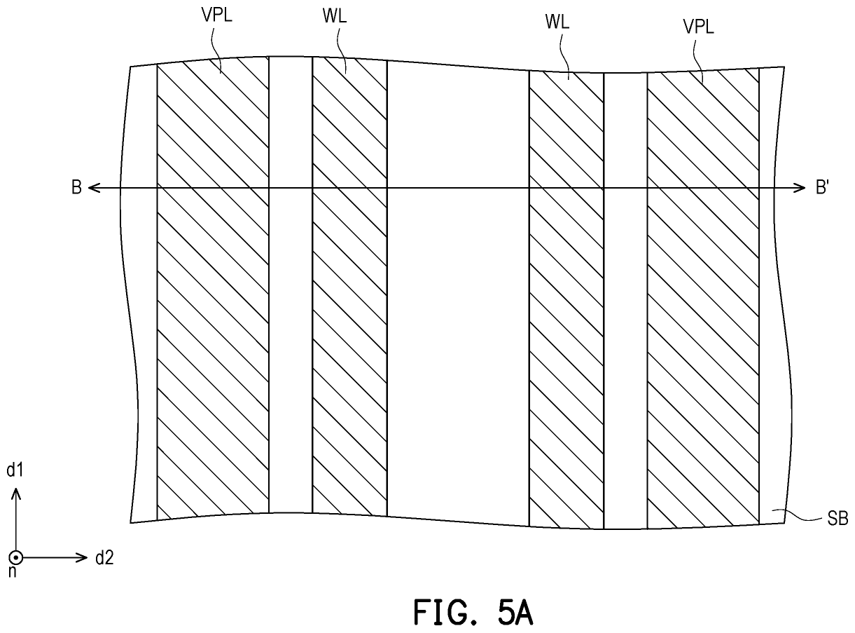

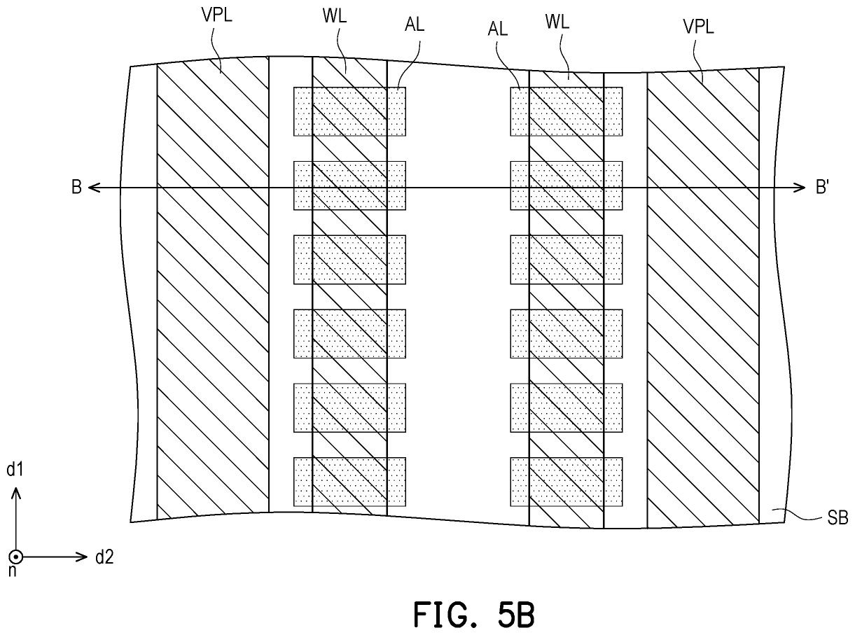

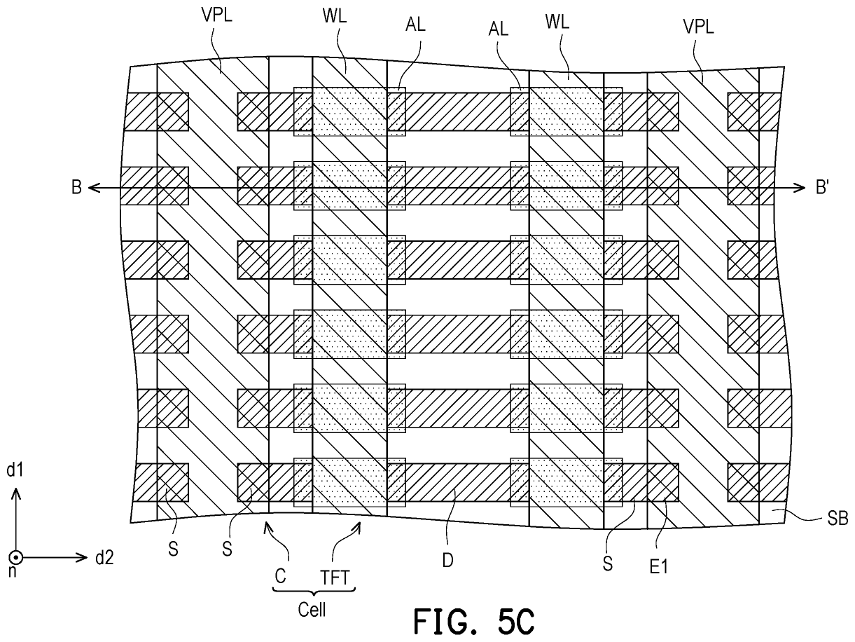

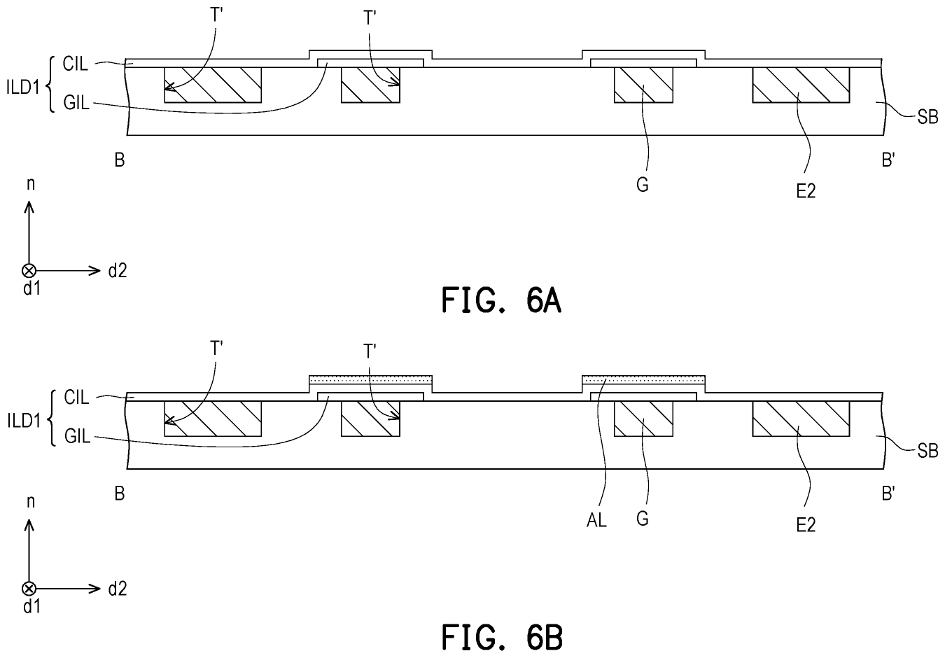

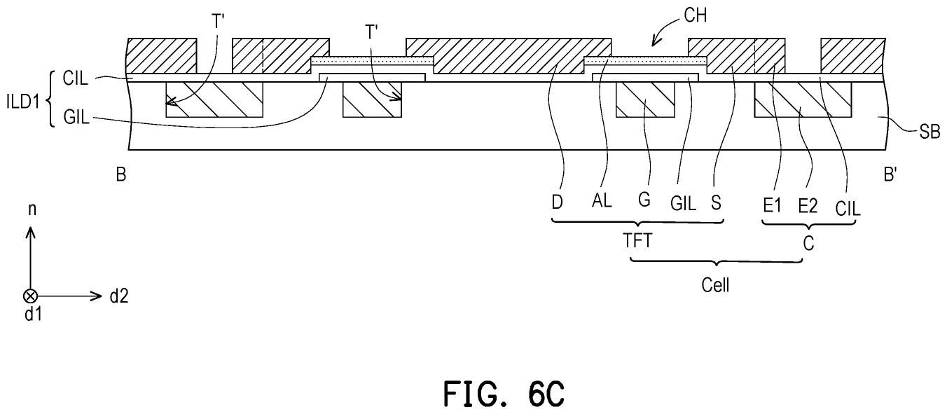

FIG. 5A to FIG. 5C are top schematic views of a method for forming a dynamic random access memory device according to the second embodiment of the disclosure, and FIG. 6A to FIG. 6C are cross-sectional schematic views of a method for forming a dynamic random access memory device according to the second embodiment of the disclosure. It is noted that the embodiments of FIG. 5A to FIG. 5C and FIG. 6A to FIG. 6C may use the reference numerals and a part of the contents of the embodiment of FIG. 4A and FIG. 4B, and the same or similar reference numerals are used to denote the same or similar elements, and the description of the same technical content is omitted.

Referring to FIG. 5A and FIG. 6A at the same time, a substrate SB is provided.

In this embodiment, the word line WL and the capacitor voltage transmission line VPL (first conductor layer) are also formed in the substrate SB. A part of the word line WL is used as the gate G of the thin film transistor TFT, and a part of the capacitor voltage transmission line VPL is used as the electrode E2 of the capacitor C. In some embodiments, the method for forming the word line WL and the capacitor voltage transmission line VPL in the substrate SB may include the following process, but the disclosure is not limited thereto. Firstly, a trench T′ is formed in the substrate SB. The trench T′ is formed, for example, by performing a patterning process to remove a part of the substrate SB. Next, a conductor material layer (not shown) filled in the trench T′ is formed on the substrate SB. Then, the conductor material layer outside trench T′ is removed to form the word line WL and the capacitor voltage transmission line VPL.

In this embodiment, a gate dielectric layer GIL is also formed on the substrate SB. The gate dielectric layer GIL covers the word line WL disposed in the trench T′ and does not cover the capacitor voltage transmission line VPL in the trench T′. In some embodiments, the method for forming the gate dielectric layer GIL on the substrate SB may include the following process, but the disclosure is not limited thereto. Firstly, a dielectric material layer (not shown) covering the substrate SB is formed on the substrate SB. Next, the gate dielectric layer GIL is formed by removing a part of the dielectric material layer by performing a patterning process.

In this embodiment, a capacitor dielectric layer CIL is also formed on the substrate SB. The dielectric layer ILD1 covers the gate dielectric layer GIL and the word line WL and the capacitor voltage transmission line VPL disposed in the trench T′.

Referring to FIG. 5B and FIG. 6B at the same time, an active layer AL is formed on the substrate SB. The active layer AL covers a part of the dielectric layer ILD1 and a part of the gate dielectric layer GIL. In some embodiments, the method for forming the active layer AL on the substrate SB may include the following process, but the disclosure is not limited thereto. Firstly, an active material layer (not shown) covering the dielectric layer ILD1 is formed on the substrate SB. Next, the active layer AL is formed by removing a part of the active material layer by performing a patterning process.

Referring to FIG. 5C and FIG. 6C at the same time, the source S and the drain D of the thin film transistor TFT and the electrode E1 (second conductor layer) of the capacitor C are formed on the substrate SB. The source S, the drain D, and the electrode E1 are disposed on the dielectric layer ILD1. In some embodiments, the method for forming the source S, the drain D, and the electrode E1 on the substrate SB may include the following process, but the disclosure is not limited thereto. Firstly, a conductor material layer (not shown) covering the dielectric layer ILD1 is formed on the substrate SB. Next, the source S, the drain D, and the electrode E1 are formed by removing a part of the conductor material layer by performing a patterning process. In this embodiment, the source S and the drain D are separated from each other, and the source S is connected to the electrode E1. In addition, the source S and the drain D partially cover the active layer AL and are electrically connected to the active layer AL. In this embodiment, drains D of adjacent thin film transistors TFT in the second direction d2 are connected to each other, as shown in FIG. 6C, but the disclosure is not limited thereto.

So far, the fabrication of the memory cell layer 200 is completed. However, the method for forming the memory cell layer 200 of the disclosure is not limited thereto.

Afterwards, referring to FIG. 4B, multiple memory cell layers 200 are stacked in the normal direction n of the substrate SB. In some embodiments, an isolation layer IL is provided between adjacent memory cell layers 200. In addition, although not shown in FIG. 4B, in other embodiments, other dielectric layers may also be disposed between adjacent memory cell layers 200, and the disclosure is not limited thereto.

Next, continuing with reference to FIG. 4B, multiple openings HL are formed in memory cell layers 200 stacked on top of each other. For example, multiple openings HL penetrate the isolation layer IL, the dielectric layer ILD1, and part of the substrate SB in the normal direction n of the substrate SB and expose part of the drain D of the thin film transistor TFT. In some embodiments, a part of the drain D may be removed when forming multiple openings HL to disconnect the drains D connected to each other in adjacent thin film transistors TFT in the second direction d2, but the disclosure is not limited thereto.

Next, continuing with reference to FIG. 4B, after forming multiple openings HL, a bit line BL (third conductor layer), which is formed by filling the conductor layer, is formed in the openings HL. Thus, in this embodiment, the bit line BL extends toward the normal direction n of the substrate SB, and the bit line BL is electrically connected to the drain D exposed by multiple openings HL.

So far, the fabrication of the dynamic random access memory device 10b with a three-dimensional structure is completed. Thereby, while increasing the storage capacity of the dynamic random access memory device 10b, the occupied area of the dynamic random access memory device 10b is reduced, so as to facilitate the integration of the dynamic random access memory device 10b. Although the method for forming the dynamic random access memory device 10b of this embodiment is described using the above method as an example, the method for forming the dynamic random access memory device of the disclosure is not limited thereto. It is worth noting that although FIG. 4B only shows three memory cell layers 200, the disclosure does not limit the amount of memory cell layers 200 included in the dynamic random access memory device 10b.

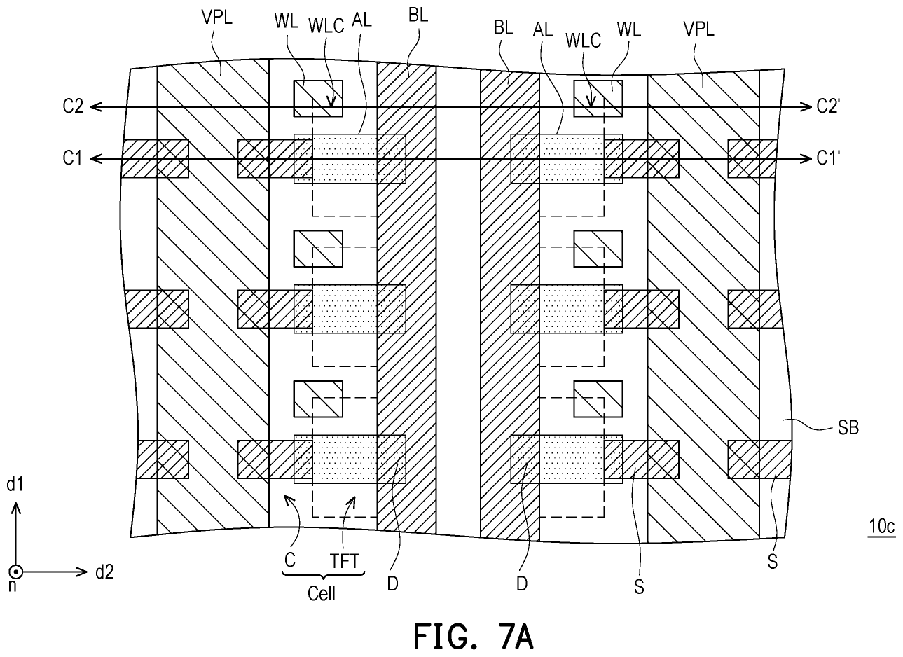

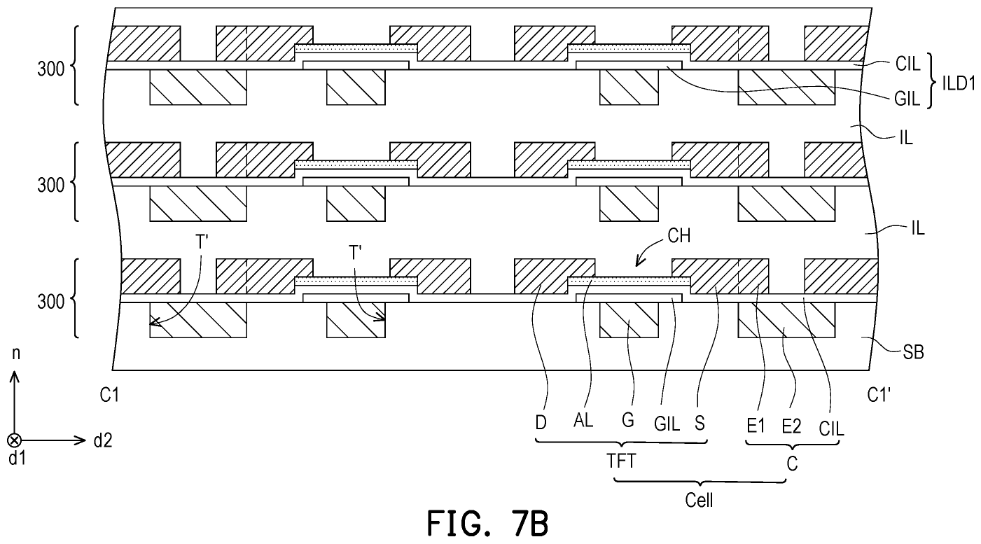

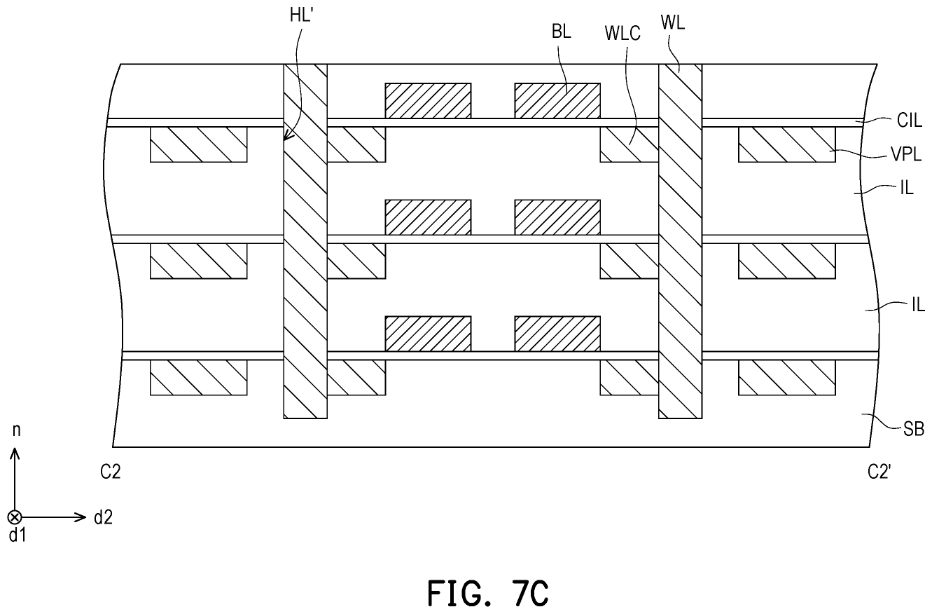

FIG. 7A is a top schematic view of a dynamic random access memory device according to the third embodiment of the disclosure, FIG. 7B is a cross-sectional schematic view cut according to the profile line C1-C1′ of FIG. 7A, and FIG. 7C is a cross-sectional schematic view cut according to the profile line C2-C2′ of FIG. 7A.

Referring to FIG. 7A, FIG. 7B, and FIG. 7C at the same time, the main difference between the dynamic random access memory device 10c of this embodiment and the dynamic random access memory device 10b is: (1) the word line WL extends toward the normal direction n of the substrate SB; (2) the drain D of the thin film transistor TFT and the bit line BL belong to the same layer; (3) the bit line BL extends toward the first direction d1.

In the aforementioned (1), the word line WL is formed in multiple openings HL′ penetrating the isolation layer IL, the dielectric layer ILD1, and a part of the substrate SB. The openings HL′ expose a part of a word line contact WLC, and the gate G of the thin film transistor TFT is connected to the word line contact WLC. Thus, the word line WL formed in the opening HL′ is electrically connected to the gate G of the thin film transistor TFT.

In the aforementioned (2), the source drain D of the thin film transistor TFT in the memory device layer 300 and the bit line BL belong to the same layer. In this embodiment, a part of bit line BL is used as the drain D of the thin film transistor TFT. That is, the drain D is directly connected to the bit line BL, but the disclosure is not limited thereto.

In the aforementioned (3), the bit line BL extends toward the first direction d1. Thus, in this embodiment, the bit line BL and the capacitor voltage transmission line VPL extend in the same direction.

Based on this, by connecting the word line WL to the word line contact WLC in the normal direction n of the substrate SB, the bit line BL and the capacitor voltage transmission line VPL are extended in the same direction and directly connected to the drain D. In this way, the integration of the dynamic random access memory device 10c is improved.

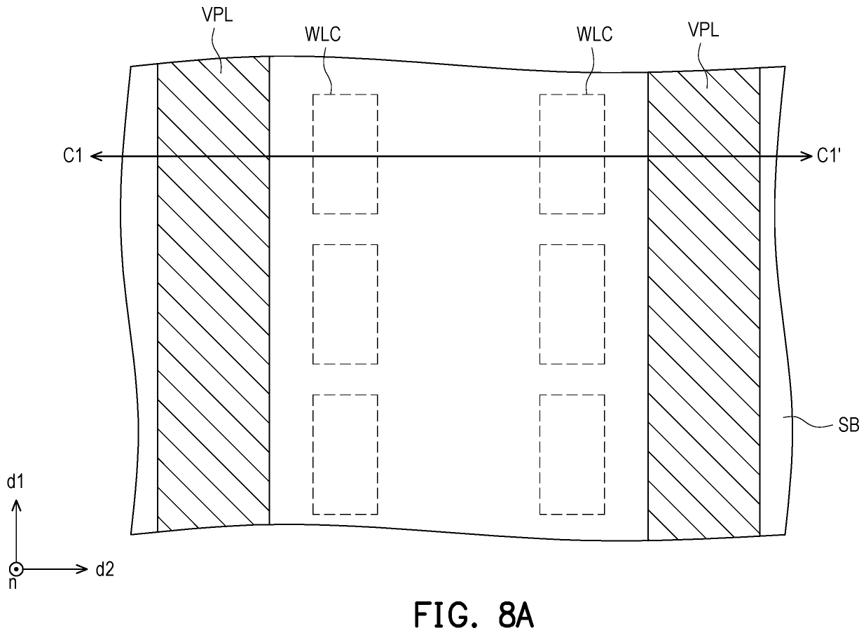

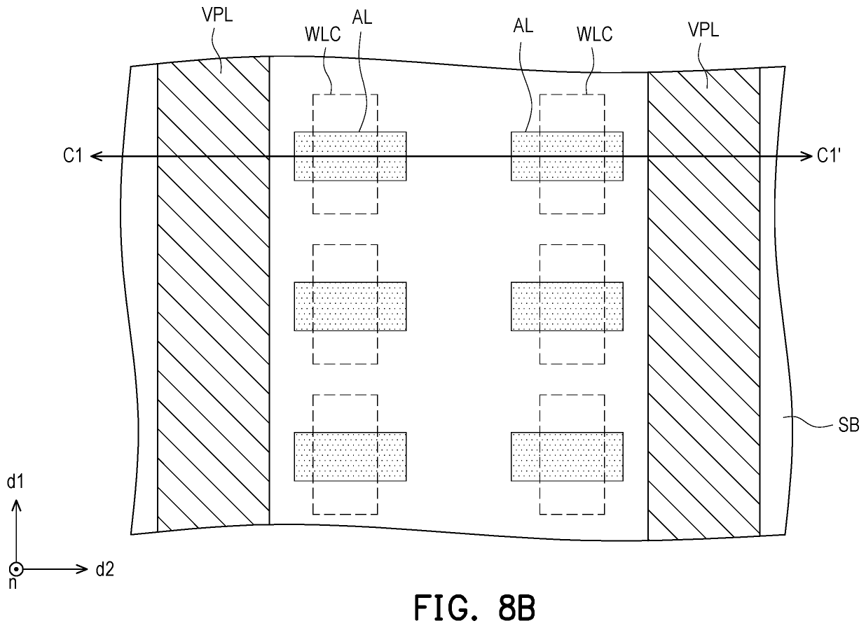

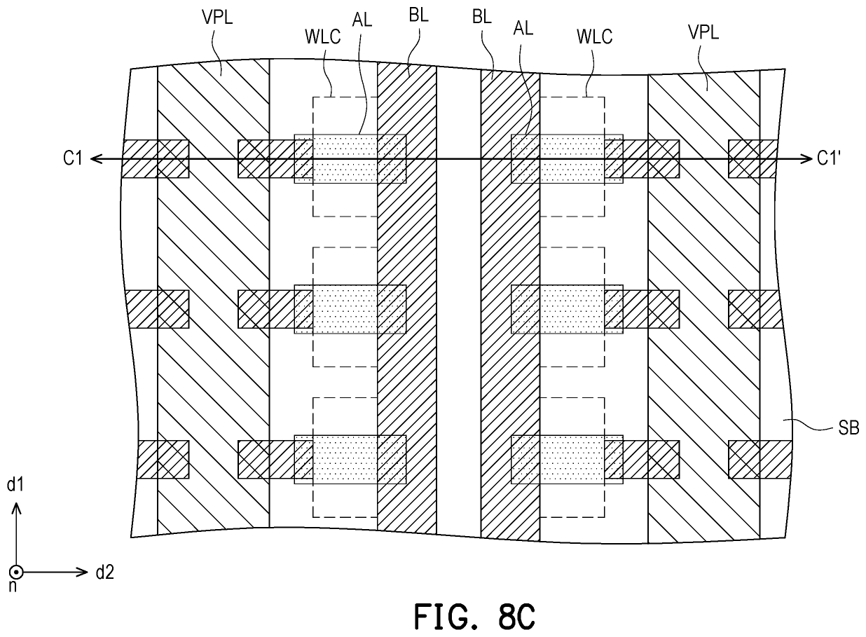

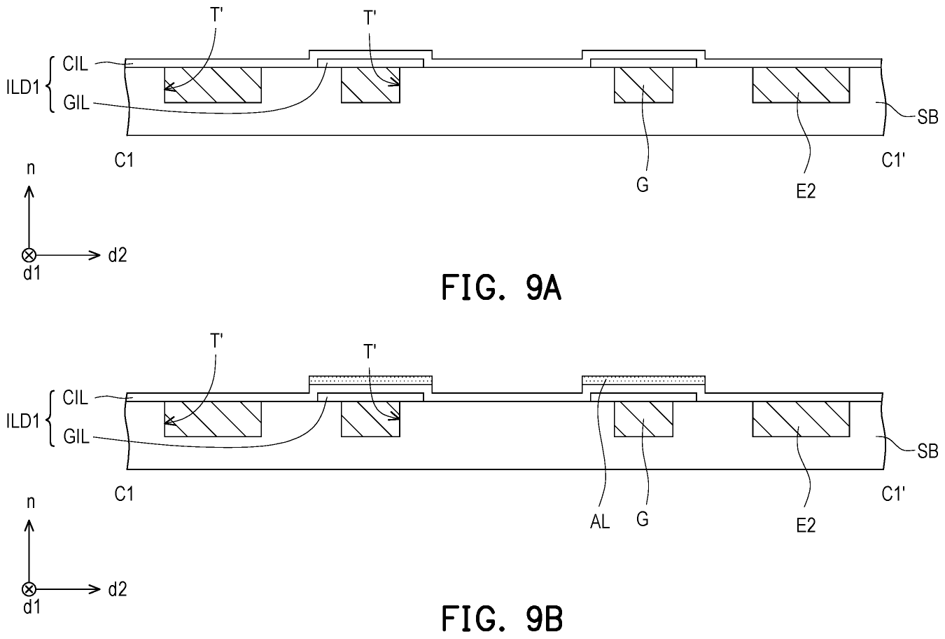

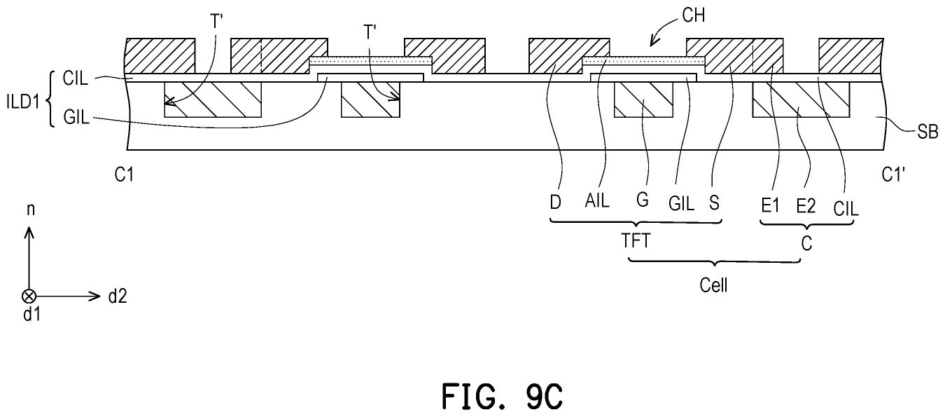

FIG. 8A to FIG. 8C are top schematic views of a method for forming a dynamic random access memory device according to the third embodiment of the disclosure, and FIG. 9A to FIG. 9C are cross-sectional schematic views of a method for forming a dynamic random access memory device according to the third embodiment of the disclosure. It is noted that the embodiments of FIG. 8A to FIG. 8C and FIG. 9A to FIG. 9C may use the reference numerals and a part of the contents of the embodiment of FIG. 7A to FIG. 7C, and the same or similar reference numerals are used to denote the same or similar elements, and the description of the same technical content is omitted.

Referring to FIG. 8A and FIG. 9A at the same time, a substrate SB is provided.

In this embodiment, the gate G, the electrode E2 of the capacitor C, and the capacitor voltage transmission line VPL (first conductor layer) are also formed in substrate SB. The electrode E2 is connected to the capacitor voltage transmission line VPL, but the disclosure is not limited thereto. In addition, in this embodiment, a word line contact WLC connected to the gate G, which is subsequently used to electrically connect the gate G to the word line WL, is also formed in the substrate SB as described in the subsequent embodiment.

In this embodiment, a gate dielectric layer GIL is also formed on the substrate SB. The gate dielectric layer GIL covers the gate G disposed in the trench T′ and does not cover the capacitor voltage transmission line VPL in the trench T′.

In this embodiment, a capacitor dielectric layer CIL is also formed on the substrate SB. The capacitor dielectric layer CIL covers the gate dielectric layer GIL and the gate G disposed in the trench T′.

Referring to FIG. 8B and FIG. 9B at the same time, an active layer AL is formed on the substrate SB. The active layer AL covers a part of the dielectric layer ILD1 and a part of the gate dielectric layer GIL.

Referring to FIG. 8C and FIG. 9C at the same time, the source S and the drain D of the thin film transistor TFT, the electrode E1 of the capacitor C, and the bit line BL (second conductor layer) are formed on the substrate SB. The source S, the drain D, the electrode E1, and the bit line BL are disposed on the dielectric layer ILD1. In this embodiment, the source S and the drain D are separated from each other. The source S is connected to the electrode E1 and the drain D is connected to the bit line BL. In addition, the source S and the drain D partially cover the active layer AL and are electrically connected to the active layer AL. In this embodiment, the bit line BL and the capacitor voltage transmission line VPL extend toward the same direction (first direction d1), but the disclosure is not limited thereto.

So far, the fabrication of the memory cell layer 300 is completed. However, the method for forming the memory cell layer 300 of the disclosure is not limited thereto.

Afterwards, referring to FIG. 7B and FIG. 7C, multiple memory cell layers 300 are stacked in the normal direction n of the substrate SB. In some embodiments, an isolation layer IL is provided between adjacent memory cell layers 300. Although not shown in FIG. 8B and FIG. 8C, in other embodiments, other dielectric layers may be provided between adjacent memory cell layers 300, and the disclosure is not limited thereto.

Next, continuing with reference to FIG. 7B and FIG. 7C, multiple openings HL′ are formed in the memory cell layers 300 stacked on each other. For example, the openings HL′ penetrate the isolation layer IL, the dielectric layer ILD1, and a part of the substrate SB in the normal direction n of the substrate SB and expose a part of the word line contact WLC.

Next, continuing with reference to FIG. 7B and FIG. 7C, after forming the openings HL′, a word line WL (third conductor layer), which is formed by filling the conductor layer, is formed in the openings HL′. Thus, in this embodiment, the word line WL extends toward the normal direction n of the substrate SB, and the word line WL is connected to the word line contact WLC exposed by the openings HL′. Thus, the word line WL formed in the opening HL′ is electrically connected to the gate G of the thin film transistor TFT.

So far, the fabrication of the dynamic random access memory device 10c with a three-dimensional structure is completed. Thereby, while increasing the storage capacity of the dynamic random access memory device 10c, the occupied area of the dynamic random access memory device 10c is reduced, so as to facilitate the integration of the dynamic random access memory device 10c. Although the method for forming the dynamic random access memory device 10c of this embodiment is described using the above method as an example, the method for forming the dynamic random access memory device of the disclosure is not limited thereto. It is worth noting that although FIG. 7B and FIG. 7C only show three memory cell layers 300, the disclosure does not limit the amount of memory cell layers 300 included in the dynamic random access memory device 10c.

To sum up, the disclosure provides a dynamic random access memory device with a three-dimensional structure and a method for forming the same, which includes multiple memory device layers stacked in the normal direction of the substrate. In addition, the thin film transistor in the memory device layer may be a vertical transistor; or the word line or the bit line extends toward the normal direction of the substrate. Based on this, the disclosure may further reduce the occupied area of the dynamic random access memory device and improve the integration of the dynamic random access memory device.

What is claimed is:

1. A dynamic random access memory device, comprising:
a substrate;
a plurality of word lines, extending toward a first direction;
a plurality of bit lines, extending toward a second direction, wherein the second direction is orthogonal to the first direction; and
a plurality of memory device layers, disposed on the substrate and stacked in a normal direction of the substrate, wherein each of the memory device layers comprises:
a plurality of memory cells, comprising a thin film transistor and a capacitor, wherein each of the memory cells is electrically connected to a corresponding word line and a corresponding bit line; and
a capacitor voltage transmission line, electrically connected to the capacitor,
wherein the word lines or the bit lines extends in a same direction as the capacitor voltage transmission line.

2. The dynamic random access memory device according to claim 1, wherein a material of a channel layer of the thin film transistor comprises an oxide semiconductor.

3. The dynamic random access memory device according to claim 2, wherein the channel layer extends toward the normal direction of the substrate.

4. The dynamic random access memory device according to claim 1, wherein the bit lines extend in the normal direction of the substrate.

5. The dynamic random access memory device according to claim 1, wherein the word lines extend toward the normal direction of the substrate.

6. The dynamic random access memory device according to claim 1, wherein a drain of the thin film transistor and the bit line belong to the same layer.

7. A method for forming a dynamic random access memory device, comprising:
providing a substrate having a trench, wherein a source of a thin film transistor and a first electrode of a capacitor are disposed in the trench;
forming a first dielectric material layer on the substrate;
forming a word line, a gate of the thin film transistor, a second electrode of the capacitor, and a capacitor voltage transmission line on the first dielectric material layer, wherein the word line and the capacitor voltage transmission line extend toward a first direction;
forming a first dielectric layer having an opening by removing a portion of the first dielectric material layer, wherein the opening of the first dielectric layer exposes a portion of the source;
forming an active layer on the substrate, wherein the active layer is electrically connected to the source;
forming a memory device layer by forming a bit line and a drain of the thin film transistor on the substrate, wherein the bit line extends toward a second direction, and the drain is electrically connected to the active layer; and
stacking a plurality of memory device layers in a normal direction of the substrate,
wherein a channel layer in the active layer and the gate are disposed correspondingly in the second direction.

8. The method for forming the dynamic random access memory device according to claim 7, further comprising forming a second dielectric layer on the gate before removing the portion of the first dielectric material layer.

9. The method for forming the dynamic random access memory device according to claim 7, wherein removing a portion of the first dielectric layer comprises:
forming a third dielectric layer on a sidewall of the gate; and
removing the portion of the first dielectric material layer by using the third dielectric layer as a mask.

10. The method for forming the dynamic random access memory device according to claim 7, wherein a fourth dielectric layer is formed on the substrate before forming the bit line and the drain of the thin film transistor on the substrate, wherein the fourth dielectric layer exposes a portion of the active layer.

11. The method for forming the dynamic random access memory device according to claim 7, wherein the first electrode of the capacitor is connected to the source to form a storage node.

12. The method for forming the dynamic random access memory device according to claim 7, wherein the second electrode of the capacitor is connected to the capacitor voltage transmission line.

13. The method for forming the dynamic random access memory device according to claim 7, wherein the drain of the thin film transistor and the bit line belong to the same layer.

14. The method for forming the dynamic random access memory device according to claim 7, wherein an isolation layer is disposed between adjacent memory device layers in the normal direction of the substrate.

15. A method for forming a dynamic random access memory device, comprising:
providing a substrate having a trench, wherein a first conductor layer is disposed in the trench, and the first conductor layer comprises a gate of a thin film transistor and a capacitor voltage transmission line;
forming a dielectric layer covering the first conductor layer on the substrate;
forming an active layer on the substrate, wherein the active layer is disposed correspondingly to the gate;
forming a memory device layer by forming a second conductor layer on the substrate, wherein the second conductor layer comprises a source and a drain of the thin film transistor, wherein the source and the drain are electrically connected to the active layer;
stacking a plurality of memory device layers in a normal direction of the substrate;
forming a plurality of openings in the memory device layers, wherein the openings extend in the normal direction of the substrate;
forming a third conductor layer in the openings,
wherein the first conductor layer further comprises a plurality of word lines and the third conductor layer comprises a plurality of bit lines; or the third conductor layer comprises the word lines and the second conductor layer further comprise the bit lines,
wherein the word lines are orthogonal to the bit lines, and the word lines or the bit lines extend in a same direction as the capacitor voltage transmission line.

16. The method for forming the dynamic random access memory device according to claim 15, wherein in response to the first conductor layer comprising the word lines and the third conductor layer comprising the bit lines, the openings expose a portion of the drain, and the bit lines are electrically connected to the drain.

17. The method for forming the dynamic random access memory device according to claim 15, wherein in response to the third conductor layer comprising the word lines and the second conductor layer comprising the bit lines, the first conductor layer further comprises a word line contact connected to the gate, the openings expose a portion of the word line contact, and the word lines are electrically connected to the word line contact.

18. The method for forming the dynamic random access memory device according to claim 15, wherein the first conductor layer further comprises a first electrode of a capacitor, and the first electrode is connected to the capacitor voltage transmission line.

19. The method for forming the dynamic random access memory device according to claim 15, wherein the dielectric layer comprises a gate dielectric layer of the thin film transistor and a capacitor dielectric layer of a capacitor.

20. The method for forming the dynamic random access memory device according to claim 15, wherein the second conductor layer further comprises a second electrode of a capacitor, and the second electrode is connected to the source.
